(19) United States
(12) Patent Application Publication
(10) Pub. No.: US 2007/0115160 A1
(43) Pub. Date: May 24, 2007

(54) Self-referenced differential decoding of analog baseband signals

(76) Inventors: Bendik Kleveland, Santa Clara, CA (US); Junfeng Xu, Palo Alto, CA (US); Thomas H. Lee, Burlingame, CA (US); Dickson Wong, Burlingame, CA (US)

Correspondence Address: Edouard Garcia, 501 Palmer Lane, Menlo Park, CA, 94025, US

(21) Appl. No.: 11/600,945

(22) Filed: Nov. 16, 2006

Related U.S. Application Data
(60) Provisional application No. 60/738,367, filed on Nov. 18, 2005.

(51) Int. Cl. H03M 1/66

(52) U.S. Cl. 341/144

(57) ABSTRACT

Apparatus and methods of differentially decoding analog baseband signals are described. In one aspect, a wireless communication apparatus includes a baseband filtering stage and a differential decoder stage. The baseband filtering stage receives a DPSK analog baseband signal differentially encoded with phase shift differences in successive symbol periods. The baseband filtering stage selectively passes frequencies in the DPSK analog baseband signal within a passband frequency range to produce a filtered analog signal. The differential decoder includes a delay circuit and a combiner circuit. The delay circuit produces from the filtered analog signal a reference signal that preserves values of a feature of the filtered analog signal for one symbol period. The combiner circuit combines values of a feature of the filtered analog signal during a current symbol period with values of the reference signal to produce a resultant signal representing a differential decoding of the DPSK analog baseband signal.

### CROSS-REFERENCE TO RELATED APPLICATIONS

Under 35 U.S.C. § 119(e), this application claims the benefit of U.S. Provisional Application No. 60/738,367, filed Nov. 17, 2005, the entirety of which is incorporated herein by reference.

### BACKGROUND

Wireless communications involve the transmission and reception of wireless signals. These communications may be one-way communications or two-way communications. Standard wireless communications modules have been developed to transition between the wireless transmission medium (usually air) and the electronic components inside wireless communication devices. A communications module may be integrally incorporated within a host system or a host system component (e.g., a network interface card (NIC)) or it may consist of a separate component that readily may be plugged into and unplugged from a host system. Wireless communication devices include wireless transmitters, wireless receivers, and wireless transceivers.

Currently, many wireless receivers have architectures that correspond to the superheterodyne receiver 10, which is shown in FIG. 1. The superheterodyne receiver 10 includes an antenna 12 that converts a wireless radio frequency (RF) signal to an electrical RF signal. An RF filter 14 filters the RF signal and a mixer 13 down-converts the filtered RF signal 15 to a lower intermediate frequency (IF) by mixing it with a signal 15 from a first local oscillator (LO1). An IF filter 16 filters the resulting IF signal 17. A pair of mixers 18, 20 down-covert the filtered IF signal 19 to a pair of quadrature phase baseband signals 22, 24 by mixing it with in-phase and in-quadrature phase versions of a second local oscillator signal 25. A pair of analog-to-digital (A/D) converters 26, 28 digitize (or quantize) the baseband signals 22, 24 and a digital signal processor (DSP) demodulator 30 decodes the digitized signals to produce the output data 32. Superheterodyne receiver architectures of the type shown in FIG. 1 tend to have high selectively and sensitivity.

Recent efforts in wireless receiver design have focused on developing receivers that have architectures that correspond to the direct conversion receiver 34, which is shown in FIG. 2. The architecture of the direct conversion receiver 34 avoids the need for any IF analog components and relaxes the selectivity requirements of the RF filter 14, allowing the size and power consumption requirements to be reduced relative to the superheterodyne receiver 10. The direct conversion receiver 34 translates the RF signal 15 directly to zero IF (i.e., an IF signal centered at zero frequency) by mixing it with in-phase and in-quadrature phase versions of a local oscillator signal 35 that has a frequency equal to the RF frequency. The resulting pair of quadrature phase baseband signals 36, 38 are filtered by respective baseband filters 40, 42 before being digitized by respective analog-to-digital (A/D) converters 44, 46 and decoded by the DSP demodulator 48.

Traditionally, both the superheterodyne architecture shown in FIG. 1 and the direct conversion architecture shown in FIG. 2 utilize multi-bit A/D converters to digitize the baseband signals and a separate DSP demodulator to decode the resulting digitized signals. These components require significant amounts of integrated circuit surface area to implement and require significant amounts of power to operate. What are needed are apparatus and methods that are capable of demodulating analog baseband signals without requiring multi-bit A/D converters and a separate digital demodulation stage.

### SUMMARY

In one aspect, the invention features a wireless communication apparatus that includes a baseband filtering stage and a differential decoder stage. The baseband filtering stage receives a differential phase shift keyed (DPSK) analog baseband signal differentially encoded with phase shift differences in successive symbol periods. The baseband filtering stage selectively passes frequencies in the DPSK analog baseband signal within a passband frequency range to produce a filtered analog signal. The differential decoder includes a delay circuit and a combiner circuit. The delay circuit produces from the filtered analog signal a reference signal that preserves values of a feature of the filtered analog signal for one symbol period. The combiner circuit combines values of a feature of the filtered analog signal during a current symbol period with values of the reference signal to produce a resultant signal representing a differential decoding of the DPSK analog baseband signal.

In another aspect, the invention features a wireless communication apparatus that includes means for receiving a differential phase shift keyed (DPSK) analog baseband signal differentially encoded with phase shift differences in successive symbol periods. The wireless communication apparatus additionally includes means for bandpass filtering the DPSK analog baseband signal by selectively passing frequencies in the DPSK analog baseband signal within a passband frequency range to produce a filtered analog signal. The wireless communication apparatus additionally includes means for producing from the filtered analog signal a reference signal that preserves values of a feature of the filtered analog signal for one symbol period. The wireless communication apparatus additionally includes means for combining values of a feature of the filtered analog signal during a current symbol period with values of the reference signal to produce a resultant signal representing a differential decoding of the DPSK analog baseband signal.

In another aspect, the invention features a wireless communication method in accordance with which a differential phase shift keyed (DPSK) analog baseband signal differentially encoded with phase shift differences in successive symbol periods is received. The DPSK analog baseband signal is bandpass filtered by selectively passing frequencies in the DPSK analog baseband signal within a passband frequency range to produce a filtered analog signal. A reference signal is produced from the filtered analog signal. The reference signal preserves values of a feature of the filtered analog signal for one symbol period. Values of a feature of the filtered analog signal during a current symbol period are combined with values of the reference signal to produce a resultant signal representing a differential decoding of the DPSK analog baseband signal.

Other features and advantages of the invention will become apparent from the following description, including the drawings and the claims.

### DESCRIPTION OF DRAWINGS

FIG. 1 is a block diagram of a prior art superheterodyne receiver.

FIG. 2 is a block diagram of a prior art direct conversion receiver.

FIG. 3 is a block diagram of an embodiment of a wireless communication apparatus in accordance with the invention.

FIG. 4 is a flow diagram of an embodiment of a wireless communication method in accordance with the invention.

FIG. 5 is a schematic diagram of an embodiment of a baseband signal path of the wireless communication apparatus of FIG. 3 that includes an embodiment of a baseband filter and an embodiment of a differential decoder.

FIG. 6A is a graph of a DPSK analog baseband signal plotted as a function of time.

FIG. 6B is a graphical representation of the DPSK analog baseband signal of FIG. 6A.

FIG. 6C is a graphical representation of DPSK analog baseband signal of FIG. 6B after being filtered by the baseband filter shown in FIG. 5.

FIG. 6D is a graphical representation of the filtered signal of FIG. 6C after being delayed by one symbol period by the delay circuit shown in FIG. 5.

FIG. 6E is a graphical representation of the resultant signal derived by mixing the filtered signal of FIG. 6C with the delayed signal of FIG. 6D.

FIG. 6F is a graphical representation of the resultant signal of FIG. 6E after being digitized by a one-bit analog-to-digital converter.

FIG. 7 is a schematic diagram of an embodiment of a differential decoder that includes an analog delay line and a mixer.

FIG. 8 is a block diagram of an embodiment of a bucket brigade analog delay line.

FIG. 9A is a circuit diagram of an embodiment of a sample-and-hold analog delay circuit.

FIG. 9B is a graph of the clock signals that are applied to the analog delay circuit of FIG. 9A to create a delay of one symbol period in accordance with an embodiment of the invention.

FIG. 10A is a schematic diagram of an embodiment of a clock generation circuit.

FIG. 10B shows graphs of an input clock signal that is applied to an input of the clock generation circuit of FIG. 10A and the resulting output clock signals that are produced by the clock generation circuit.

FIG. 11A is a schematic diagram of an embodiment of a differential decoder that includes a threshold detector and a digital delay line.

FIG. 11B is a schematic diagram of an embodiment of a biasing circuit for generating a bias signal for the digital delay line shown in FIG. 11A.

FIG. 12A is a schematic diagram of an embodiment of a differential decoder that includes a hysteresis buffer and a digital delay line.

FIG. 12B is a graph of an exemplary input-output characteristics of the hysteresis buffer shown in FIG. 12B.

FIG. 13 is a schematic diagram of an embodiment of a differential decoder.

FIG. 14 is a schematic diagram of an embodiment of a baseband signal path of the wireless communication apparatus of FIG. 3 that includes an embodiment of a baseband filter and an embodiment of a differential decoder.

FIG. 15 is a flow diagram of an embodiment of a wireless communication method that is executed by the wireless communication apparatus of FIG. 14.

FIG. 16A is a graphical representation of the DPSK analog baseband signal of FIG. 6A.

FIG. 16B is a graphical representation of DPSK analog baseband signal of FIG. 16A after being filtered by the baseband filter shown in FIG. 14.

FIG. 16C is a graphical representation of a first reference signal that is produced by the differential decoder circuit of FIG. 14 with a respective high logic value for one symbol period in response to each detection of a rising edge of the filtered signal of FIG. 16B.

FIG. 16D is a graphical representation of a second reference signal that is produced by the differential decoder circuit of FIG. 14 with a respective high logic value for one symbol period in response to each detection of a falling edge of the filtered signal of FIG. 16B.

FIG. 16E is a graphical representation of the resultant signal derived by combining the first and second reference signals of FIGS. 16C and 16D through the logical NOR gate of FIG. 14.

FIG. 17 is a schematic diagram of a superheterodyne receiver embodiment of the wireless communication apparatus shown in FIG. 3.

FIG. 18 is a schematic diagram of a direct conversion receiver embodiment of the wireless communication apparatus shown in FIG. 3.

### DETAILED DESCRIPTION

In the following description, like reference numbers are used to identify like elements. Furthermore, the drawings are intended to illustrate major features of exemplary embodiments in a diagrammatic manner. The drawings are not intended to depict every feature of actual embodiments nor relative dimensions of the depicted elements, and are not drawn to scale. Although many of the drawings show the interconnections between wireless communication apparatus components as single lines, this representation is used merely for ease of illustration and is not intended to limit these embodiments to a single-ended mode of signal transmission. Instead, each of these interconnections is intended to depict both (i) a single wire (or trace) that supports a single-ended mode of signal transmission in which a signal propagates down the single wire and (ii) a pair of wires (or traces) that support a differential mode of signal transmission in which differential signals propagate down the pair of wires. As used herein, the term “signal” refers to both (i) a single signal, and (ii) a differential pair of signals carrying information in their differences.

I. Introduction

The embodiments that are described herein are capable of demodulating analog baseband signals without requiring multi-bit A/D converters in each baseband signal path and a separate downstream demodulation stage. As explained in detail below, these embodiments perform a self-referenced differential decoding of the analog baseband signals. In this process, values of a feature of each analog baseband signal are preserved for one symbol period and are combined with values of a feature of the baseband signal during a current symbol period to derive a resultant signal representing the differential decoding of the analog baseband signal. In this way, these embodiments are expected to enable wireless receivers to be implemented with significantly reduced sizes and significantly reduced power consumption requirements. In addition, the self-referenced differential decoding processes that are performed by the embodiments in accordance with the invention are expected to be able to differentially decode analog baseband signals even in the presence of significant direct current (DC) drift. As a result, wireless receivers in accordance with these embodiments may be implemented with relatively small DC blocking capacitors, thereby enabling reductions in the overall size of the receiver circuits and the time needed to recover from a standby mode of operation.

As used herein the term “wireless” refers to any form of non-wired signal transmission, including AM and FM radio transmission, TV transmission, cellular telephone transmission, portable telephone transmission, and wireless LAN (local area network) transmission. A wide variety of different methods and technologies may be used to provide wireless transmissions in the embodiments that are described herein, including infrared line of sight methods, cellular methods, microwave methods, satellite methods, packet radio methods, and spread spectrum methods.

The wireless communication apparatus that are described herein may be implemented by relatively small, low-power and low-cost integrated circuit stages that are integrated on a single semiconductor chip. As a result, these apparatus are highly suitable for incorporation in wireless communications environments that have significant size, power, and cost constraints, including but not limited to handheld electronic devices (e.g., a mobile telephone, a cordless telephone, a portable memory device such as a smart card, a personal digital assistant (PDA), a video camera, a still image camera, a solid state digital audio player, a CD player, an MCD player, a game controller, and a pager), portable computers (e.g., laptop computers), computer peripheral devices (e.g., input devices, such as computer mice), and other embedded environments.

II. Architecture and Operation of a Wireless Communication Apparatus

A. Overview

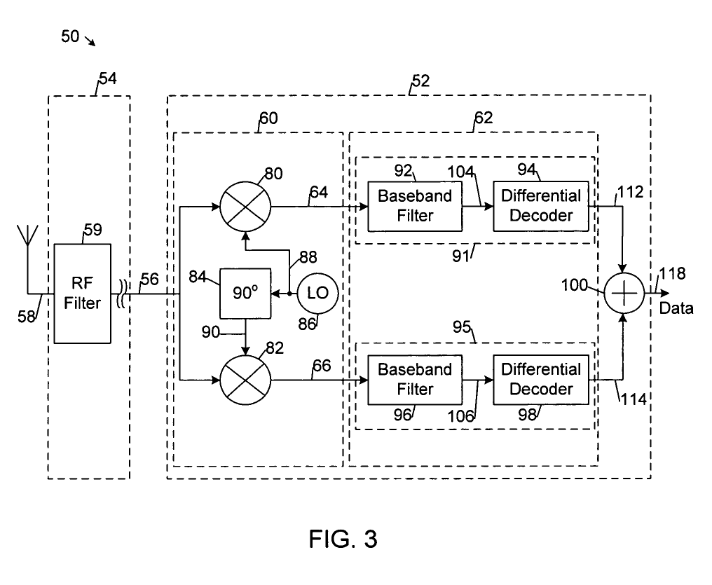

FIG. 3 shows an exemplary application environment 50 in which an embodiment of a wireless communication apparatus 52 may operate. The application environment 50 includes an input stage 54 that produces an input signal 56 from wireless signals that are received by an antenna 58. The input stage 54 includes an RF filter 59 that filters an electrical RF signal that is received from the antenna 58. In some embodiments, the resulting filtered RF signal is the input signal 56. In other embodiments, the input stage 54 includes one or more additional components (e.g., analog IF circuitry) that process the filtered RF signal before outputting the input signal 56.

In the illustrated embodiments, the input signal 56 includes a carrier wave that is modulated with a data-carrying signal. The frequency of the carrier wave may correspond to the frequency of the wireless signals that are received by the antenna 58, or they may correspond to a lower intermediate frequency. The data-carrying signal is encoded in accordance with a differential phase shift keyed (DPSK) encoding protocol. The data-carrying signal may be encoded in accordance with any differential phase shift keying protocol that encodes data as phase shift differences between successive symbol periods. In general, the data-varying signal is encoded with data in accordance with a differential M-PSK protocol, which uses M phases (corresponding to M equally spaced points on a PSK constellation diagram) to encode log₂M bits per symbol, where M has an integer value of at least two. For example, in some embodiments, the data-carrying signal is encoded with data in accordance with the Differential Binary Phase Shift Keying (DBPSK) protocol (M=2), which is used for 1 Mbps transmissions in accordance with the IEEE 802.11 wireless local area networking protocol. In other embodiments, the data-varying signal is encoded with data in accordance with the Differential Quadrature Phase-shift Keying (DQPSK) protocol (M=4).

The wireless communication apparatus 52 includes a down-conversion stage 60 and a baseband processing stage 62.

The down-conversion stage 60 extracts from the input signal 56 in-phase and quadrature-phase DPSK analog baseband signals 64, 66 that correspond to the constituent data-carrying signal of the input signal 56. The down-conversion stage 60 includes a first mixer 80, a second mixer 82, a phase-shifter 84, and a local oscillator 86 (LO). The local oscillator 86 is coupled to the first mixer 80 and the phase shifter 84. The phase-shifter 84 is coupled between the local oscillator 86 and the second mixer 82. In operation, the local oscillator 86 produces an in-phase local oscillator signal 88. The phase-shifter 84 produces an in-quadrature version 90 of the local oscillator signal 88. The first mixer 80 produces the in-phase DPSK baseband signal 64 by mixing the input signal 56 with the in-phase local oscillator signal 88. The second mixer 82 produces the quadrature-phase DPSK baseband signal 66 by mixing the input signal 56 with the in-quadrature version 90 of the local oscillator signal 88.

The frequencies of resulting DPSK analog baseband signals 64, 66 are in a specified baseband frequency range. As used herein, the baseband frequency range refers to the frequency range from 0 Hertz (Hz) up to a maximum frequency that is substantially below the frequency range of the input signal 56. In typical RF applications, the maximum baseband frequency typically is below 100 MHz, whereas the maximum frequency of the input signal 56 typically is in the GHz frequency range.

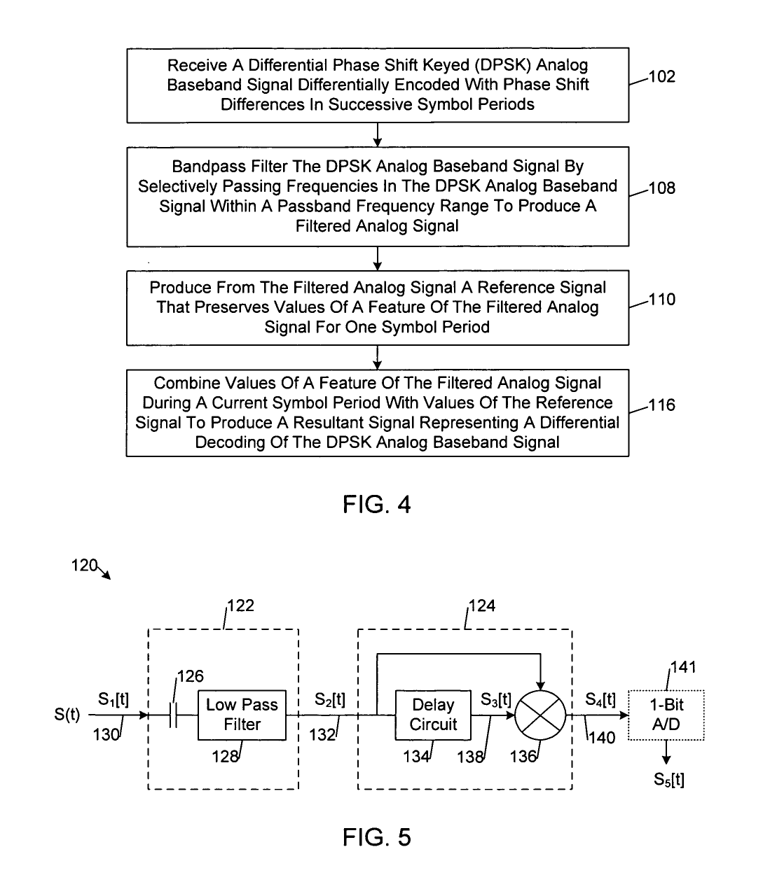

The baseband processing stage 62 includes a first baseband signal path 91 that includes a first baseband filter 92 and a first differential decoder 94, and a second baseband signal path 95 that includes a second baseband filter 96 and a second differential decoder 98. Some embodiments of the baseband processing stage 62 process the in-phase and quadrature-phase DPSK analog baseband signals 64, 66 in accordance with the wireless communication method shown in FIG. 4. In accordance with this method, each of the baseband filters 92, 96 receives a corresponding one of the in-phase and quadrature-phase DPSK analog baseband signals 64, 66 from the down-conversion stage 60 (FIG. 4, block 102). Each of the bandpass filters 92, 96 bandpass filters the corresponding one of the DPSK analog baseband signals 64, 66 by selectively passing frequencies in the DPSK analog baseband signal 64, 66 within a passband frequency range to produce a respective filtered analog signal 104, 106 (FIG. 4, block 108). Each of the differential decoders 94, 98 produces from a corresponding one of the filtered analog signals 104, 106 a respective reference signal that preserves values of a feature of the filtered analog signal 104, 106 for one symbol period (FIG. 4, block 110). Each of the differential decoders 94, 98 combines values of a feature of the corresponding filtered analog signal 104, 106 during a current symbol period with values of the respective reference signal to produce a respective resultant signal 112, 114 representing a differential decoding of the corresponding DPSK analog baseband signal 64, 66 (FIG. 4, block 116).

In the illustrative embodiment shown in FIG. 3, an adder 100 combines the resultant signals 112, 114 to produce output data 118. In some embodiments, the adder 100 simply interleaves the resultant signals 112, 114 to produce the output data 118.

B. Variations and Additional Features of the Wireless Communication Apparatus

In some wireless communication apparatus embodiments in accordance with the invention, the down-conversion stage 60 includes only one of the mixers 80, 82, and the baseband processing stage 62 includes only one of the in-phase and quadrature phase baseband signal paths 91, 95. These embodiments typically do not include the adder 100.

In some wireless communication apparatus embodiments in accordance with the invention, the baseband processing stage 82 include additional components (e.g., one or more amplifier circuits and a gain control circuit) that are not shown in the drawings.

III. Exemplary Baseband Signal Path Embodiments and Their Components

A. Introduction

This section describes embodiments of the baseband signal paths 91, 95 and their components. The following description focuses on the aspects of the baseband signal paths that relate to baseband filtering and differential decoding. This focus is not intended to imply that these signal path embodiments consist of only baseband filtering and differential decoding components. To the contrary, each of the baseband signal paths typically includes one or more additional components. For example, each of the baseband signal paths typically include one or more amplification circuits. In some embodiments, each baseband signal path includes a variable gain amplifier circuit located between the baseband filtering stage and the differential decoder.

### B. A First Baseband Signal Path Embodiment

1. Overview

FIG. 5 shows an embodiment of a baseband signal path 120 that includes a baseband filtering stage 122 and a differential decoder 124.

The baseband filtering stage 122 includes a high-pass filtering DC blocking capacitor 126 and a low-pass filter 128. Together, the capacitor 126 and the low-pass filter 128 reject interferers in an input DPSK analog baseband signal 130 that are outside a selected passband (or channel) frequency range. A bandpass-filtered analog signal 132 is produced at the output of the low-pass filter 128.

The differential decoder 124 includes a delay circuit 134 and a mixer 136. The delay circuit 134 produces from the filtered analog signal 132 a reference signal 138 that preserves values of a feature of the filtered analog signal 132 for one symbol period. In this embodiment, the preserved feature values are correlated with values (e.g., voltage values) of the filtered analog signal 132. In some implementations, these feature values are analog representations of the filtered analog signal values. In other implementations these feature values are digital representations of the filtered analog signal values. The mixer 136 combines values of a feature of the filtered analog signal during a current symbol period with values of the reference signal 138 to produce an output resultant signal 140 representing a differential decoding of the DPSK analog baseband signal 130.

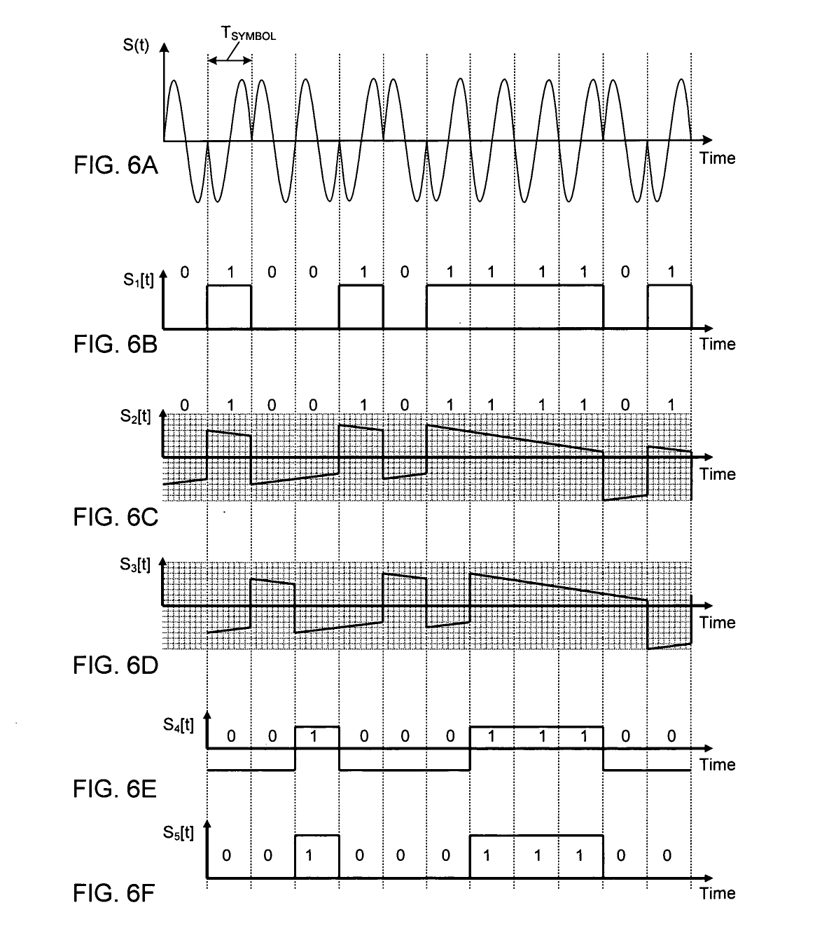

Graphical representations of the values of exemplary signals at various points along the baseband signal path 120 are shown in FIGS. 6A-6F.

FIG. 6A shows a graph of an example of the DPSK analog baseband signal 130 (S(t)) plotted as a function of time. In this illustrative example, binary data (i.e., the symbol sequence shown in FIG. 6F) is encoded as phase shift differences between successive symbol periods (T_{SYMBOL}) in accordance with an exemplary DBPSK encoding protocol. For illustrative purposes only, the DPSK analog baseband signal S(t) is represented herein by a binary signal s₁[t] that represents the different phase states of the DPSK analog baseband signal S(t) with binary 1's and 0's, as shown in FIG. 6B.

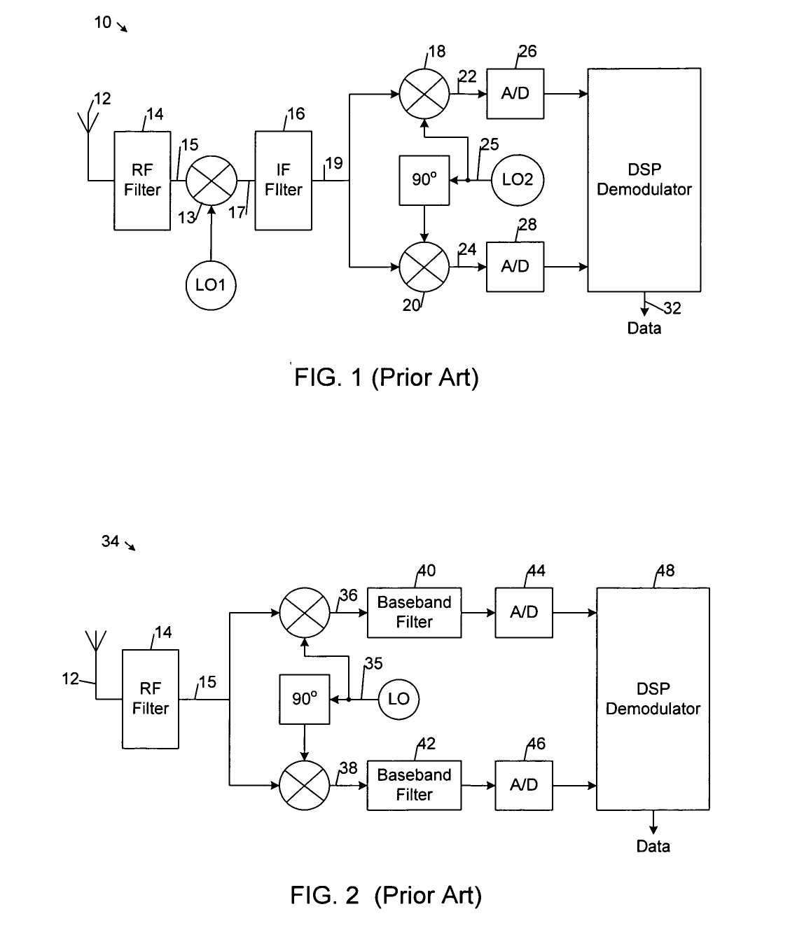

FIG. 6C shows a binary signal s₂[t] that graphically represents the DPSK analog baseband signal S(t) after being filtered by the baseband filtering stage 122. As shown, the relatively small DC blocking capacitor 126 produces significant DC drift. In this illustrative example, the DC drift may make it difficult to decode the signal with a simple comparison with a zero voltage reference. For example, at time t₁, the high logic value of the signal s₂[t] is nearly zero. In order to successfully decode such a signal using the prior art approaches shown in FIGS. 1 and 2, the multi-bit A/D converters 26, 28, 44, 46 would need a high resolution (e.g., on the order of the small squares in the grids that are superimposed on the graphs shown in FIGS. 6C and 6D) in order to subtract out the drift in the digital domain. As explained above, however, such high-resolution A/D converters require large chip areas and consume significant power, making them less desirable for highly integrated, low-power applications.

FIG. 6D shows a binary signal s₃[t] that graphically represents the reference signal 138, which corresponds to the filtered signal s₂[t] after being delayed by one symbol period by the delay circuit 134.

FIG. 6E shows a binary signal s₄[t] that graphically represents the resultant signal 140, which is derived by mixing the filtered signal s₂[t] with the reference signal s₃[t] in the mixer 136. The mixing of the filtered signal s₂[t] with the reference signal S₃[t], which represents the values of a characteristic feature of the filtered signal, effectively corresponds to the performance of a logical XNOR operation on the phase states of the DPSK analog baseband signal S(t) in successive symbol periods, where the logical XNOR operation produces a high logic value when there is no phase state change between successive symbol periods and a low logic value when there is a phase state change between successive symbol periods.

Referring back to FIG. 5, in some embodiments, the resultant signal s₄[t] is digitized by an optional one-bit analog-to-digital converter 141 (or a slicer circuit) to produce the digital signal s₅[t] shown in FIG. 6F. The digital signal s₅[t] corresponds to the data was differentially encoded in successive phases of the DPSK analog baseband signal S(t) shown in FIG. 6A.

2. Differential Decoder Embodiments

In general, the differential decoder 124 may be implemented by any circuit that produces from the filtered analog signal 132 a reference signal that preserves values of a feature of the filtered analog signal 132 for one symbol period, and combines values of a feature of the filtered analog signal 132 during a current symbol period with values of the reference signal to produce a resultant signal representing a differential decoding of the corresponding DPSK analog baseband signal 130. The following illustrative embodiments represent only a small selection of the wide variety of different ways in which the differential decoder 124 may be implemented.

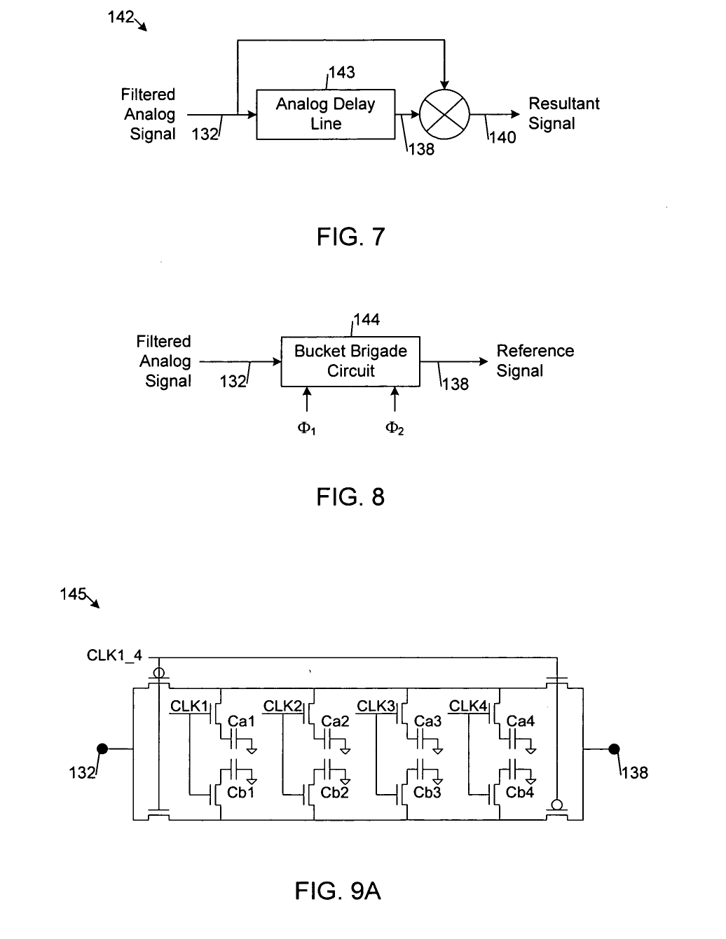

FIG. 7 shows an embodiment of a differential decoder 142 in which the delay circuit is implemented by an analog delay line 143, which produces an analog delay of the filtered analog signal 132 by one symbol period (e.g., T_{SYMBOL}). In general, the analog delay line 143 may be implemented in any of a wide variety of different ways. Exemplary types of analog delay line circuits include bucket brigade delay circuits and sample-and-hold delay circuits.

FIG. 8 shows an embodiment of a bucket brigade circuit 144 that may be used as the analog delay line 143. The bucket brigade circuit 144 is triggered by two phase-shifted input clock signals (Φ₁ and Φ₂) that operate at a frequency higher than the frequency of the filtered analog signal 132. The bucket brigade circuit 144 produces an analog delay of the filtered analog signal 132 by one symbol period. In this process, the amplitude of the filtered analog signal 132 is preserved in the reference signal 138. In a typical implementation, the bucket brigade circuit, samples the filtered analog signal 132 at successive clock pulses. The samples are stored as charges on a line of capacitors. At each successive clock pulse, the charge on each capacitor is passed on to the next capacitor in the line. The reference signal 138 is output from the last capacitor in the line. Thus, the reference signal 138 is a delayed version of the filtered analog signal 132. The length of the delay, which depends on the number of stages and the clock frequency, is set to one symbol period (e.g., T_{SYMBOL})

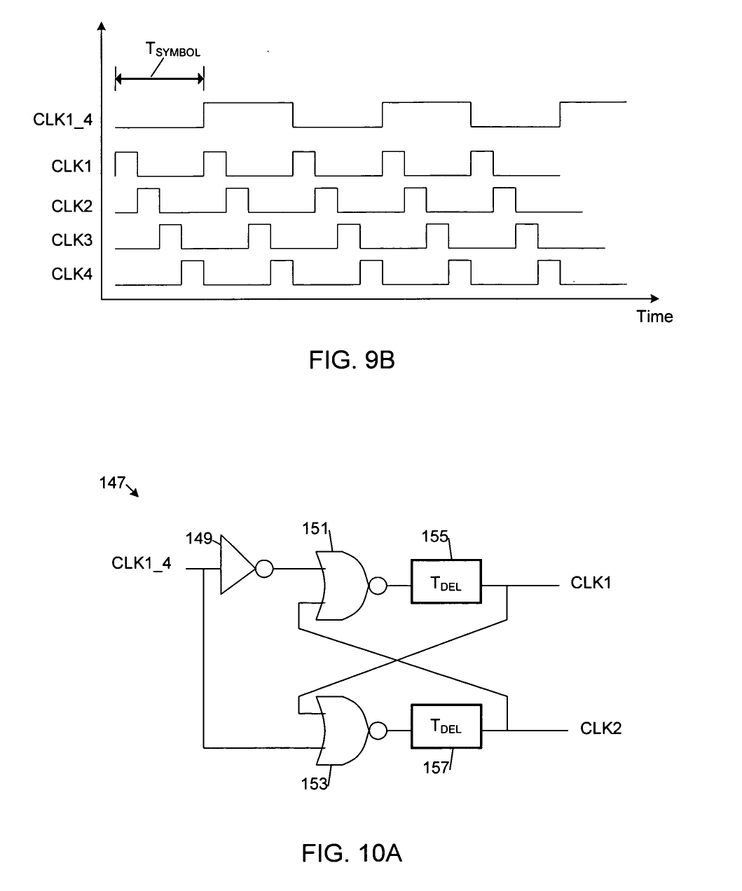

FIG. 9A shows an embodiment of a sample-and-hold circuit 145 that may be used as the analog delay line 143. The sample-and-hold circuit 145 is similar to the bucket brigade circuit 144 because it samples the filtered analog signal 132, stores the analog voltages on capacitors Ca1, Cb1, Ca2, Cb2, Ca3, Cb3, Ca4, Cb4, and requires clocks (CLK1, CLK2, CLK3, CLK4) that operate at a frequency higher than the frequency of the filtered analog signal 132. The sample-and-hold circuit 190, however, does not require any charge transfer along a long capacitor chain, and therefore typically can operate with lower power and lower noise than the bucket brigade circuit 144. In operation, the filtered analog signal 132 is sampled and held for a clock period using non-overlapping sub-clock signals (CLK1, CLK2, CLK3, CLK4) that are derived from a clock signal CLK1_4, which operates with a period equal to the twice the symbol period (e.g., T_{SYMBOL}). The resolution of the delay period depends on the number of sub-clock signals that are used. In some embodiments, the sub-clock signals are shared with over-sampling circuitry that is used to search for the rising and falling edges of the filtered analog signal 132 edges in the digital domain.

FIG. 9B shows a time plot of the clock signals (CLK1_4, CLK1, CLK2, CLK3, CLK4) that are applied to the sample-and-hold circuit 145 to create a delay of one symbol period in accordance with an embodiment of the invention.

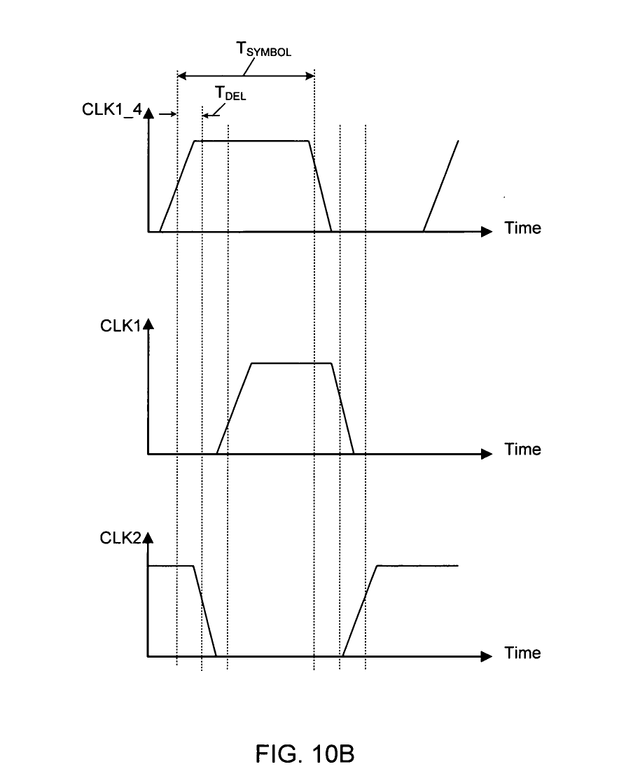

FIG. 10A shows an embodiment of a clock generation circuit 147 that generates the sub-clock signals CLK1 and CLK2 from the clock signal CLK1_4. The clock generation circuit 147 is a NOR flip-flop that includes an inverter 149, two NOR gates 151, 153, and two delay circuits 155, 157. As shown in FIG. 10B, the rising edge of the clock signal CLK1_4 causes the clock signal CLK2 to fall after a delay of T_{DEL}. Next, after another delay of T_{DEL}, the clock signal CLK1 rises. The falling edge of the clock signal CLK1_4 causes the clock signal CLK1 to fall after a delay of T_{DEL}. Next, after another delay of T_{DEL}, the clock signal CLK2 rises. The clock signals CLK3 and CLK4 may be generated in an analogous way.

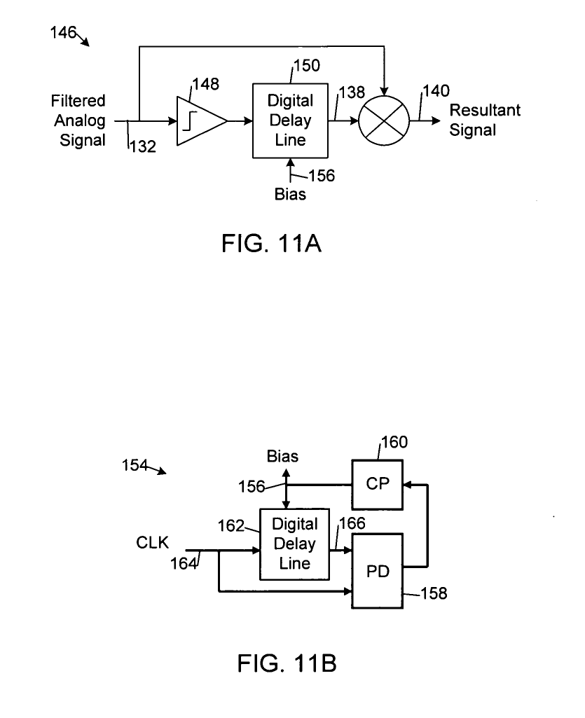

FIG. 11A shows an embodiment of a differential decoder 146 in which the delay circuit is implemented by a threshold detector 148 and a digital delay line 150. The threshold detector 148 may be implemented by a comparator circuit that digitizes the filtered analog signal 132 at zero crossings. The digital delay line 150 delays the resulting digital signal 152 by one symbol period (e.g., T_{SYMBOL}). In general, the digital delay line 150 may be implemented in any of a wide variety of different ways. The digital delay line 150 typically is implemented by digital components, such as transistor-transistor logic (TTL) components, CMOS components, and emitter-coupled logic (ECL) components.

FIG. 11B shows an embodiment of a biasing circuit 154 that generates a bias voltage 156 for the digital delay line 150 in the differential decoder 146 shown in FIG. 11A. The biasing circuit 154 includes a phase detector 158 (PD), a charge pump 160 (CP), and a digital delay line 162 that is equivalent to the digital delay line 150. In operation, the digital delay line produces a clock signal 166 at an input of the phase detector 158. The clock signal 166 corresponds to a delayed version of a clock signal 164, which has a period equal to one symbol period (e.g., T_{SYMBOL}). The phase detector 158 transmits to the charge pump 160 up or down signals 166 that adjust the bias voltage 156, which is applied to both of the digital delay lines 150, 162. The output of the charge pump 160 is fed back to the digital delay line 162. When the clock signals 164, 166 are aligned, the output of the charge pump is stabilized and the bias signal 156 corresponds to the bias level needed to produce a delay of one symbol period in the digital delay line 150.

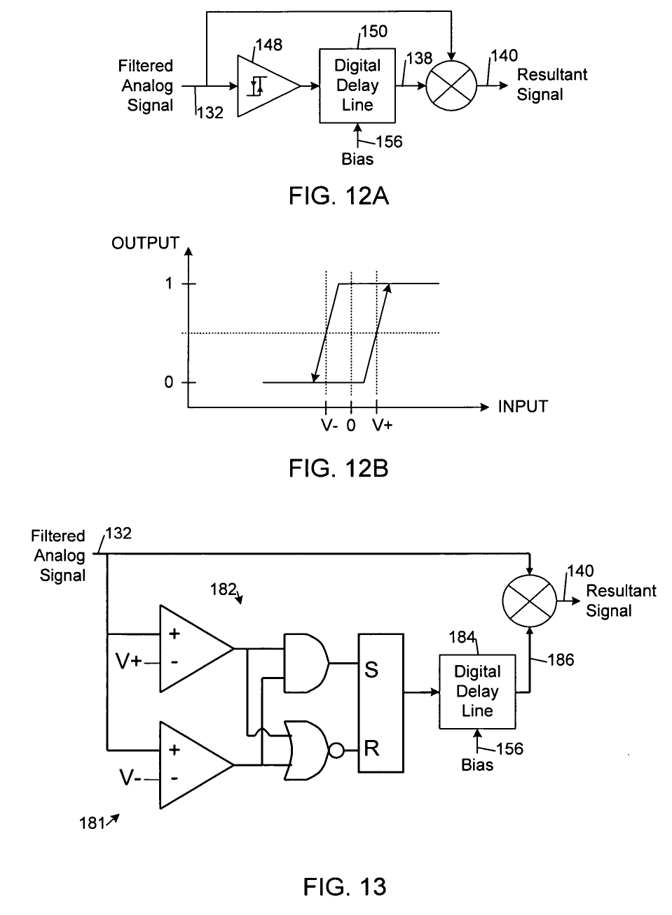

FIG. 12A shows an embodiment of a differential decoder 170 in which the delay circuit is implemented by a hysteresis buffer 172 and a digital delay line 174. The hysteresis buffer 172 may be implemented by a standard hysteresis buffer circuit that digitizes the filtered analog signal 132 at zero crossings. FIG. 12B shows an input-output characteristic of an exemplary implementation of the hysteresis buffer 172, where V+ and V− are the upper and lower transition thresholds. The hysteresis in the hysteresis buffer 172 suppresses unwanted triggering from noise signals around the zero crossings. The digital delay line 174 delays the resulting digital signal 176 by one symbol period (e.g., T_{SYMBOL}). In general, the digital delay line 174 may be implemented in any of a wide variety of different ways. In some embodiments, the digital delay line 174 is implemented in the same way as the digital delay line 150 shown in FIG. 8A and biased by the biasing circuit 154 shown in FIG. 11B.

FIG. 13 shows an embodiment of a differential decoder 180 that includes a delay circuit 181, which is implemented by a hysteresis circuit 182 and a digital delay line 184. The hysteresis circuit 182 digitizes the filtered analog signal 132 at zero crossings. The suppression unwanted triggering from noise signals around the zero crossings is controllable through the adjustment of the reference voltages V+ and V−. In some embodiments, these reference voltages are adjusted by a variable gain amplifier gain control feedback loop. The digital delay line 184 delays the resulting digital signal 186 by one symbol period (e.g., T_{SYMBOL}). In general, the digital delay line 184 may be implemented in any of a wide variety of different ways. In some embodiments, the digital delay line 184 is implemented in the same way as the digital delay line 150 shown in FIG. 11A and biased by the biasing circuit 154 shown in FIG. 11B.

### C. A Second Baseband Signal Path Embodiment

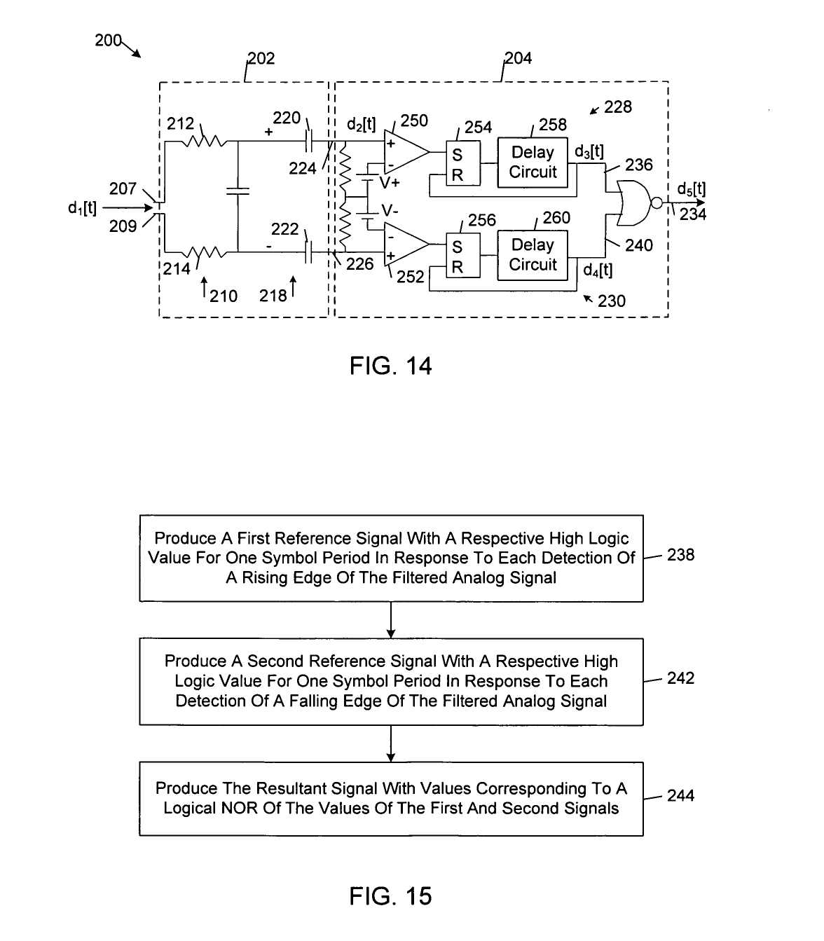

FIG. 14 shows an embodiment of a baseband signal path 200 that includes a baseband filtering stage 202 and a differential decoder 204. As shown explicitly in FIG. 14, the baseband signal path 20 is formed by positive and negative differential signal branches 206, 208 that support propagation of a differential pair of DPSK analog baseband signals 207, 209.

The baseband filtering stage 122 includes a differential low-pass filter circuit 210 that includes a respective resistor 212, 214 on each differential signal branch 206, 208 and a capacitor 216 that is coupled across the differential signal branches 206, 208. The baseband filtering stage 122 also includes a differential high-pass filter circuit 218 that is located downstream of the differential low-pass filter circuit 210 and includes a respective DC blocking capacitor 220, 222 in each differential signal branch 206, 208. Together, the low-pass filter circuit 210 and the high-pass filter circuit 218 reject interferers in the differential pair of DPSK analog baseband signals 207, 209 that are outside a selected passband (or channel) frequency range. Differential bandpass-filtered analog signals 224, 226 are produced at the outputs of the differential high-pass filter circuit 218.

The differential decoder 204 includes in the positive differential signal branch 206 a first one-shot circuit 228 in the positive differential signal branch 206 and a second one-shot circuit 230 in the negative differential signal branch. As explained in detail below, the first one-shot circuit 228 is triggered on rising edges of the positive differential filtered analog signal 224 and the second one-shot circuit 230 is triggered on falling edges of the negative differential filtered analog signal 226. The differential decoder 200 additionally includes a NOR logic gate 232 that has inputs coupled to the outputs of the first and second one-shot circuits 228, 230 and an output that produces a resultant signal 234 representing a differential decoding of the differential pair of DPSK analog baseband signals 207, 209.

FIG. 15 shows an embodiment of a method that is implemented by the differential decoder 204. In accordance with this embodiment, the first one-shot circuit 228 produces a first reference signal 236 with a respective high logic value for one symbol period in response to each detection of a rising edge of the positive differential filtered analog signal 224 (FIG. 15, block 238). The second one-shot circuit 230 produces a second reference signal 240 with a respective high logic value for one symbol period in response to each detection of a falling edge of the negative differential filtered analog signal 226 (FIG. 15, block 242). The NOR gate 232 produces the resultant signal 234 with values that correspond to the logical NOR of the values of the first and second reference signals 236, 240 (FIG. 15, block 244).

In the illustrated embodiment, each of the first and second one-shot circuits 228, 230 is implemented by a respective edge detector 250, 252 and a respective monostable delay circuit. Each of the edge detectors 250, 252 typically is implemented by a comparator circuit. Each of the monostable delay circuits is implemented by a respective SR latch 254, 256 coupled to a respective delay circuit 258, 260 with a feedback loop that delays the output of the corresponding SR latch by one symbol period (e.g., T_{SYMBOL}). In general, the first and second one-shot circuits 228, 230 may be implemented by any type of one shot circuits that output pulses that are one symbol in length in response to the detection of positive and negative edges of the differential filtered analog signals 224, 226.

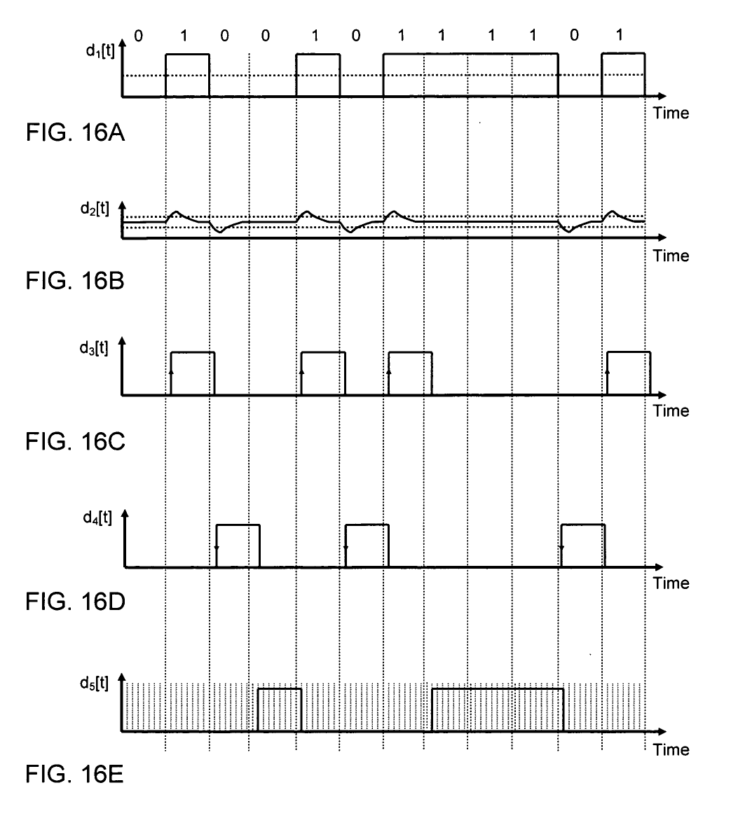

Graphical representations of the values of the signals at various points along the baseband signal path 200 are shown in FIGS. 16A-16E.

For illustrative purposes only, the differential pair of DPSK analog baseband signals 207, 209 are represented herein by a binary signal d₁[t] that represents the different phase states of the differential pair of DPSK analog baseband signals 207, 209 with binary 1's and 0's. As shown in FIG. 16A, in this example, the signal d₁[t] corresponds to the signal s₁[t] shown in FIG. 6B.

FIG. 16B shows a binary signal d₂[t] that graphically represents the differential pair of DPSK analog baseband signals 207, 209 after being filtered by the baseband filtering stage 202 (see FIG. 14).

FIG. 16C shows a binary signal d₃[t] that graphically represents the reference signal 236, which has logic high pulses that are one symbol period in length and begin shortly after the rising edges of the positive differential filtered analog signal 224 (see FIG. 14). FIG. 16D shows a binary signal d₄[t] that graphically represents the reference signal 240, which has logic high pulses that are one symbol period in length and begin shortly after the falling edges of the negative differential filtered analog signal 226 (see FIG. 14). The reference signals d₃[t] and d₄[t] represent the values of characteristic features of the differential filtered signals 224, 226 (namely, the rising and falling edges).

FIG. 16E shows a binary signal d₅[t] that graphically represents the resultant signal 234, which is derived by combining the reference signals 236, 240 in accordance with a logical NOR operation. The series of dashed lines shown in FIG. 16E correspond to the times at which the signal d₂[t] is sampled. The logical NOR of the reference signals d₃[t] and d₄[t] effectively corresponds to the performance of a logical XNOR operation on the phase states of the differential pair of DPSK analog baseband signals 207, 209 in successive symbol periods, where the logical XNOR operation produces a high logic value with there is no phase state change between successive symbol periods and a low logic value when there is a phase state change between successive symbol periods.

### IV. Exemplary Embodiments of the Wireless Communication Apparatus and its Components

### A. An Exemplary Superheterodyne Receiver Embodiment

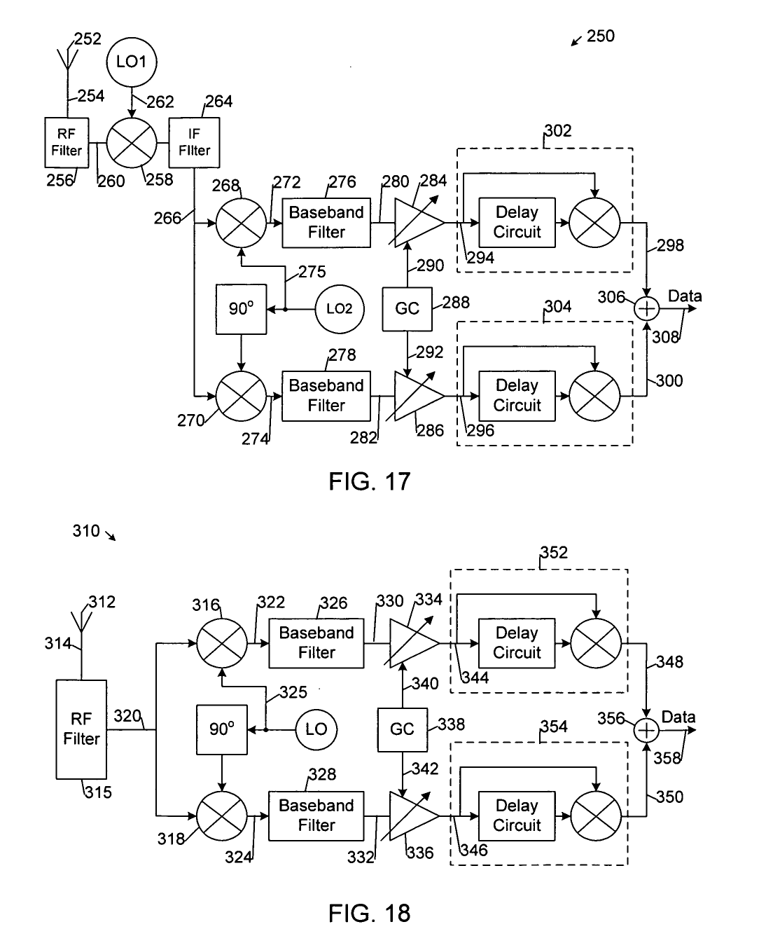

FIG. 17 shows an embodiment of a superheterodyne receiver 250 that includes an embodiment of the wireless communication apparatus 52. The superheterodyne receiver 250 includes an antenna 252 that converts a wireless radio frequency (RF) signal to an electrical RF signal 254. An RF filter 256 filters the RF signal 254 and a mixer 258 down-converts the filtered RF signal 260 to a lower intermediate frequency (IF) by mixing it with a first local oscillator signal 262. An IF filter 264 filters the resulting IF signal 266. A pair of mixers 268, 270 down-covert the filtered IF signal 266 to a pair of quadrature phase baseband signals 272, 274 by mixing it with in-phase and in-quadrature phase versions of a second local oscillator signal 275.

The baseband signals 272, 274 are filtered by baseband filters 276, 278, respectively. In general, the baseband filters 272, 274 may be implemented by any of the baseband filter embodiments described herein. In the illustrated embodiment, each of the baseband filters 276, 278 is implemented by a respective instance of the baseband filter 122 shown in FIG. 5.

The resulting baseband filtered signals 280, 282 are amplified respectively by an amplification stage that includes first and second amplification circuits 284, 286 and a gain controller 288. The first and second amplification circuits 284, 286 are implemented by variable gain amplifiers whose gains are controlled by respective gain control signals 290, 292 that are set by the gain controller 288. The gain controller 288 includes one or more detector circuits that produce measurement signals indicative of the power levels of the first and second baseband signals 294, 296 that are output from the first and second amplification circuits 284, 286, respectively. In some implementations, the detector circuits produce DC measurement signals that are proportional to the RMS (root mean square) of the power levels of first and second baseband signals 294, 296. The gain controller 288 sets the gain control signals 290, 292 based on an integration of the differences between the DC measurement signals and reference voltage levels.

The first and second baseband signals 294, 296 are decoded into respective resultant signals 298, 300 by differential decoders 302, 304. In general, the differential decoders 352, 354 may be implemented by any of the differential decoder embodiments described herein. In the illustrated embodiment, each of the differential decoders 302, 304 is implemented by a respective instance of the differential decoder 124 shown in FIG. 5.

The resultant signals 298, 300 are combined by an adder 306 to produce the output data 308.

Another direct conversion embodiment corresponds to the direct conversion receiver 250 except that the baseband filter 276 and the differential decoder 302 in the in-phase baseband signal path are replaced by respective instances of the bandpass filtering stage 202 and the differential decoder stage 204 shown in FIG. 14. Similarly, the baseband filter 278 and the differential decoder 304 in the in-phase baseband signal path are replaced by respective instances of the bandpass filtering stage 202 and the differential decoder stage 204 shown in FIG. 14.

### B. An Exemplary Direct Conversion Receiver Embodiment

FIG. 18 shows an embodiment of a direct conversion receiver 310 that includes an embodiment of the wireless communication apparatus 52. The direct conversion receiver 310 includes an antenna 312 that converts a wireless radio frequency (RF) signal to an electrical RF signal 314. An RF filter 315 filters the RF signal 314. A pair of mixers 316, 318 down-covert the filtered RF signal 320 to a pair of quadrature phase baseband signals 322, 324 by mixing it with in-phase and in-quadrature phase versions of a local oscillator signal 325

The baseband signals 322, 324 are filtered by baseband filters 326, 328, respectively. In general, the baseband filters 326, 328 may be implemented by any of the baseband filter embodiments described herein. In the illustrated embodiment, each of the baseband filters 326, 328 is implemented by a respective instance of the baseband filter 122 shown in FIG. 5.

The resulting baseband filtered signals 330, 332 are amplified respectively by an amplification stage that includes first and second amplification circuits 334, 336 and a gain controller 338. The first and second amplification circuits 334, 336 are implemented by variable gain amplifiers whose gains are controlled by respective gain control signals 340, 342 that are set by the gain controller 338. The gain controller 338 includes one or more detector circuits that produce measurement signals indicative of the power levels of the first and second baseband signals 344, 346 that are output from the first and second amplification circuits 334, 336, respectively. In some implementations, the detector circuits produce DC measurement signals that are proportional to the RMS (root mean square) of the power levels of first and second baseband signals 344, 346. The gain controller 338 sets the gain control signals 340, 42 based on an integration of the differences between the DC measurement signals and reference voltage levels.

The first and second baseband signals 344, 346 are decoded into respective resultant signals 348, 350 by differential decoders 352, 354. In general, the differential decoders 352, 354 may be implemented by any of the differential decoder embodiments described herein. In the illustrated embodiment, each of the differential decoders 352, 354 is implemented by a respective instance of the differential decoder 124 shown in FIG. 5.

The resultant signals 248, 350 are combined by an adder 356 to produce the output data 358.

Another direct conversion embodiment corresponds to the direct conversion receiver 310 except that the baseband filter 326 and the differential decoder 352 in the in-phase baseband signal path are replaced by respective instances of the bandpass filtering stage 202 and the differential decoder stage 204 shown in FIG. 14. Similarly, the baseband filter 328 and the differential decoder 354 in the in-phase baseband signal path are replaced by respective instances of the bandpass filtering stage 202 and the differential decoder stage 204 shown in FIG. 14.

V. Conclusion

The embodiments that are described herein are capable of demodulating analog baseband signals without requiring multi-bit A/D converters in each baseband signal path and a separate downstream demodulation stage. As explained in detail below, these embodiments perform a self-referenced differential decoding of the analog baseband signals. In this process, values of a feature of each analog baseband signal are preserved for one symbol period and are combined with values of a feature of the baseband signal during a current symbol period to derive a resultant signal representing the differential decoding of the analog baseband signal. In this way, these embodiments are expected to enable wireless receivers to be implemented with significantly reduced sizes and significantly reduced power consumption requirements. In addition, the self-referenced differential decoding processes that are performed by the embodiments in accordance with the invention are expected to be able to differentially decode analog baseband signals even in the presence of significant direct current (DC) drift. As a result, wireless receivers in accordance with these embodiments may be implemented with relatively small DC blocking capacitors, thereby enabling reductions in the overall size of the receiver circuits and the time needed to recover from a standby mode of operation.

Other embodiments are within the scope of the claims.

What is claimed is:

1. A wireless communication apparatus, comprising:
a baseband filtering stage operable to receive a differential phase shift keyed (DPSK) analog baseband signal differentially encoded with phase shift differences in successive symbol periods, the baseband filtering stage being operable to selectively pass frequencies in the DPSK analog baseband signal within a passband frequency range to produce a filtered analog signal; and
a differential decoder comprising a delay circuit and a combiner circuit, wherein the delay circuit produces from the filtered analog signal a reference signal that preserves values of a feature of the filtered analog signal for one symbol period, and the combiner circuit combines values of a feature of the filtered analog signal during a current symbol period with values of the reference signal to produce a resultant signal representing a differential decoding of the DPSK analog baseband signal.

2. The apparatus of claim 1, wherein the delay circuit comprises: a delay line that delays the filtered analog signal by one symbol period to produce the reference signal; and the combiner circuit comprises a mixer that mixes the filtered analog signal with the reference signal to produce the resultant signal.

3. The apparatus of claim 2, wherein the differential decoder comprises a one-bit analog-to-digital converter that converts the resultant signal to a differentially decoded digital signal.

4. The apparatus of claim 2, wherein the delay line comprises an analog delay line circuit that delays the filtered analog signal by one symbol period.

5. The apparatus of claim 2, wherein the delay line comprises a digitizer that produces a digitized signal from the filtered analog signal, and a digital delay line circuit that delays the digitized signal by one symbol period to produce the reference signal.

6. The apparatus of claim 5, wherein the digitizer comprises a zero-crossing threshold detector that produces the digitized signal with values representing zero-crossings in the filtered analog signal.

7. The apparatus of claim 5, wherein the digitizer comprises a level sensing hysteresis circuit that produces the digitized signal from the filtered analog signal.

8. The apparatus of claim 2, wherein the delay line comprises a sample-and-hold circuit that is clocked by multiple non-overlapping clock signals each having a respective period equal to the sample period.

9. The apparatus of claim 1, comprising:
a first mixer that mixes an input signal with an in-phase local oscillator (LO) signal to produce the DPSK analog baseband signal;
a second mixer that mixes the input signal with an in-quadrature version of the LO signal to produce a quadrature-phase DPSK analog baseband signal;
an in-phase signal path that includes the baseband filtering stage, the differential decoder, and has an in-phase output that produces the output signal representing the differential decoding of the DPSK analog signal;
a quadrature-phase signal path that includes a second baseband filtering stage equivalent to the first baseband filtering stage, a second differential decoder equivalent to the first differential decoder, and has a quadrature-phase output that produces a second output signal representing a differential decoding of the quadrature-phase DPSK analog baseband signal.

10. The apparatus of claim 9, further comprising: an adder having a first input coupled to the in-phase output, a second input coupled to the quadrature-phase output, and an adder output that outputs the resultant signal; and a one-bit analog-to-digital coupled to the adder output and operable to convert the resultant signal into digital data representing a digital decoding of the DPSK analog baseband signal.

11. The apparatus of claim 9, further comprising a third mixer operable to downconvert an RF signal to produce an intermediate frequency (IF) signal; and an IF filter coupled to the third mixer and operable to filter the IF signal to produce the input signal.

12. The apparatus of claim 1, wherein the baseband filtering stage comprises a high pass filtering coupling capacitor coupled to an input of a low pass filter circuit.

13. The apparatus of claim 1, wherein:
the delay circuit produces the reference signal with a respective high logic value for one symbol period in response to each detection of a rising edge of the filtered analog signal, and the delay circuit additionally produces a second reference signal with a respective high logic value for one symbol period in response to each detection of a falling edge of the filtered analog signal; and
the combiner circuit produces the resultant signal with values corresponding to a logical NOR of the values of the first and second signals.

14. The apparatus of claim 1, wherein the delay circuit comprises a first one-shot circuit that is triggered on rising edges of the filtered analog signal and a second one-shot circuit that is triggered on falling edges of the filtered analog signal, and the combiner circuit comprises a NOR logic gate having inputs coupled to the first and second one-shot circuits and an output that produces the resultant signal.

15. The apparatus of claim 14, wherein each of the first and second one-shot circuits comprises: an edge detector that extracts an edge feature of the filtered analog signal; a set-reset latch having a set input coupled to the edge detector, a reset input, and a latch output; and a delay line that has an input coupled to the latch output, and an output that is coupled to the reset input of the latch and one of the inputs of the NOR logic gate.

16. The apparatus of claim 14, wherein the baseband filtering stage comprises a low pass filter circuit having differential inputs coupled to receive the DPSK analog signal as a differential pair of signals and differential outputs each coupled through a respective high pass filtering coupling capacitor to an input of a respective one of the first and second one-shot circuits.

17. A wireless communication method, comprising:
receiving a differential phase shift keyed (DPSK) analog baseband signal differentially encoded with phase shift differences in successive symbol periods;
bandpass filtering the DPSK analog baseband signal by selectively passing frequencies in the DPSK analog baseband signal within a passband frequency range to produce a filtered analog signal;
producing from the filtered analog signal a reference signal that preserves values of a feature of the filtered analog signal for one symbol period; and
combining values of a feature of the filtered analog signal during a current symbol period with values of the reference signal to produce a resultant signal representing a differential decoding of the DPSK analog baseband signal.

18. The method of claim 17, wherein the producing comprises delaying the filtered analog signal by one symbol period to produce the reference signal, and the combining comprises mixing the filtered analog signal with the reference signal to produce the resultant signal.

19. The method of claim 17, wherein:
the producing comprises producing the reference signal with a respective high logic value for one symbol period in response to each detection of a rising edge of the filtered analog signal, and producing a second reference signal with a respective high logic value for one symbol period in response to each detection of a falling edge of the filtered analog signal; and
the combining comprises producing the resultant signal with values corresponding to a logical NOR of the values of the first and second reference signals.

20. A wireless communication apparatus, comprising:
means for receiving a differential phase shift keyed (DPSK) analog baseband signal differentially encoded with phase shift differences in successive symbol periods;
means for bandpass filtering the DPSK analog baseband signal by selectively passing frequencies in the DPSK analog baseband signal within a passband frequency range to produce a filtered analog signal;
means for producing from the filtered analog signal a reference signal that preserves values of a feature of the filtered analog signal for one symbol period; and
means for combining values of a feature of the filtered analog signal during a current symbol period with values of the reference signal to produce a resultant signal representing a differential decoding of the DPSK analog baseband signal.
